(19) United States
(12) Patent Application Publication
(10) Pub. No.: US 2010/0140773 A1
(43) Pub. Date: Jun. 10, 2010

(54) STACKED CHIP, MICRO-LAYERED LEAD FRAME SEMICONDUCTOR PACKAGE

(76) Inventors: Manolito Fabres Galera, Singapore (SG); Leocadio Morona Alabin, Singapore (SG)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/332,207

(22) Filed: Dec. 10, 2008

(51) Int. Cl. H01L 23/58; H01L 21/00

(52) U.S. Cl. 257/686; 438/109; 257/E23.002; 257/E21.001

(57) ABSTRACT

Semiconductor packages that contain stacked chips on a micro-layered lead frame and methods for making such semiconductor packages are described. The semiconductor packages contain a full array of land pads that has been formed from a lead frame. The packages comprise multiple chips that are stacked vertically and separated by routing leads which are connected to the land pad array. The routing leads can be etched from a metal cladding layer that is provided between each set of stacked chips. Each chip and its routing leads can be encapsulated before the next chip is provided in the package. The semiconductor packages therefore have a high input/output capability with a small package footprint, a flexible routing capability, and a small thickness for multiple chips that are stacked in the package. Other embodiments are also described.

### CROSS-REFERENCE TO RELATED APPLICATION

This patent application claims priority of U.S. application Ser. No. 12/199,065, filed Aug. 27, 2008, the entire disclosure of which is hereby incorporated by reference.

### FIELD

This application relates generally to semiconductor devices and methods for making such devices. More specifically, this application describes semiconductor packages that contain stacked chips on a micro-layered lead frame and methods for making such semiconductor packages.

### BACKGROUND

Semiconductor packages are well known in the art. Often, these packages may include one or more semiconductor devices, such as an integrated circuit (“IC”) die or chip, which may be connected to a die pad that is centrally formed in a lead frame which contain a series of leads. In some cases, bond wires electrically connect the IC die to a series of terminals that serve as an electrical connection to an external device, such as a printed circuit board (“PCB”). An encapsulating material can be used to cover the bond wires, the IC die, the terminals, and/or other components of the semiconductor device to form the exterior of the semiconductor package. A portion of the terminals and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package is often used in an ever growing variety of electronic applications, such as disk drives, USB controllers, portable computer devices, cellular phones, and so forth. Depending on the die and the electronic application, the semiconductor package may be highly miniaturized and may need to be as small as possible.

### SUMMARY

This application relates to semiconductor packages that contain stacked chips on a micro-layered lead frame and methods for making such semiconductor packages. The semiconductor packages contain a full array of land pads that has been formed from a lead frame. The packages comprise multiple chips that are stacked vertically and separated by routing leads which are connected to the land pad array. The routing leads can be etched from a metal cladding layer that is provided between each set of stacked chips. Each chip and its routing leads can be encapsulated before the next chip is provided in the package. The semiconductor packages therefore have a high input/output capability with a small package footprint, a flexible routing capability, and a small thickness for multiple chips that are stacked in the package.

### BRIEF DESCRIPTION OF THE DRAWINGS

The following description can be better understood in light of the Figures, in which:

FIG. 1 shows some embodiments of a method for making semiconductor packages containing a lead frame with vias;

FIG. 2 depicts some embodiments of a method for making semiconductor packages containing a first semiconductor die;

FIG. 3 shows some embodiments of a method for making semiconductor packages containing a first pre-molding layer;

FIGS. 4 and 5 respectively depict a plan view and side view of some embodiments of a method for making semiconductor packages containing a metal cladding layer;

FIGS. 6 and 7 respectively depict a plan view and side view of some embodiments of a method for making semiconductor packages containing a metal cladding layer with a cavity;

FIG. 8 depicts some embodiments of a method for making semiconductor packages containing an interconnect structure with routing leads;

FIG. 9 depicts some embodiments of a method for making semiconductor packages containing a second semiconductor die;

FIG. 10 depicts some embodiments of a method for making semiconductor packages containing a second pre-molding layer;

FIG. 11 depicts some embodiments of a method for making semiconductor packages containing a second interconnect structure with routing leads;

FIG. 12 depicts some embodiments of a method for making semiconductor packages containing a third semiconductor die;

FIG. 13 depicts some embodiments of a method for making semiconductor packages containing a molding layer;

FIG. 14 depicts a bottom view of some embodiments of a semiconductor package containing a land pattern;

FIG. 15 depicts some embodiments of a method for making semiconductor packages showing a singulated package

FIGS. 16-17 depict side views of some embodiments of a method for making semiconductor packages showing a singulated package;

FIG. 18 shows some embodiments of a method for making semiconductor packages containing a lead frame with vias;

FIG. 19 depicts a plan view and a side view of some embodiments of a method for making semiconductor packages containing a first and second semiconductor die;

FIG. 20 shows some embodiments of a method for making semiconductor packages containing a pre-molding layer;

FIG. 21 depicts some embodiments of a method for making semiconductor packages containing an interconnect structure with routing leads;

FIG. 22 depicts some embodiments of a method for making semiconductor packages containing a third semiconductor die;

FIG. 23 depicts some embodiments of a method for making semiconductor packages containing a molding layer;

FIG. 24 depicts a bottom view of some embodiments of a semiconductor package containing a land pattern; and

FIGS. 25-26 depict some embodiments of a method for making semiconductor packages showing a singulated package.

The Figures illustrate specific aspects of the semiconductor packages and methods for making such packages. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the devices and associated methods of making and using the devices can be implemented and used without employing these specific details. Indeed, the devices and associated methods can be placed into practice by modifying the illustrated devices and associated methods and can be used in conjunction with any other apparatus and techniques conventionally used in the industry. For example, while the description below focuses on methods for making for semiconductor packages in the IC industry, it could be used in and applied to other electronic devices like optoelectronic devices, solar cells, MEMS structures, lighting controls, power supplies, and amplifiers.

Some embodiments of the semiconductor packages and methods for making such packages are shown in FIGS. 1-17. In these embodiments, the methods for making the semiconductor packages begin by providing a leadframe 10. The leadframe supports a die (or dies) that will be placed thereon, serves as part of the input/output (I/O) interconnection system, and also provides a thermally conductive path for dissipating some of the heat generated during operation. The material of the leadframe 10 can comprise any conductive metal or metal alloy known in the art, including Cu, Ni—Pd, Fe, Fe alloy, Ni—Pd—Au, Ni—Pd—Au/Ag, or combinations thereof. In some embodiments, the leadframe comprises Cu with Ni—Au or Ni—Ag plating.

In some instances, the leadframe 10 can contain a layer of metal plating (not shown) if desired. For example, the leadframe (or lead frame) 10 may be electroplated or otherwise coated with a layer of a solderable conductive material, such as tin, gold, lead, silver, and/or another solderable material. In some embodiments, the leadframe 10 can have one or more recesses that define a die pad (or die attach pad) that supports a semiconductor die. For example, as shown in FIG. 1, the leadframe 10 contains an upper surface with a recess that operates as a die attach pad 18 and which is sized and shaped to allow the desired semiconductor die to be disposed thereon.

Next, vias 12 can be provided on the upper surface of the lead frame 10 if the leadframe is not made with vias 12 already present. The vias 12 can be formed on the lead frame 10 using any known technique in the art, including any known masking and etching process which removes the material of the lead frame 10 where the vias 12 do not need to be present. In some instances, the vias 12 are formed while the lead frame 10 is being manufactured. The thickness of the vias 12 will depend on the leadframe thickness, and in some configurations the vias can have half of the thickness of the leadframe. In some embodiments, the vias 12 can have a thickness ranging from about 50 μm to about 112 μm.

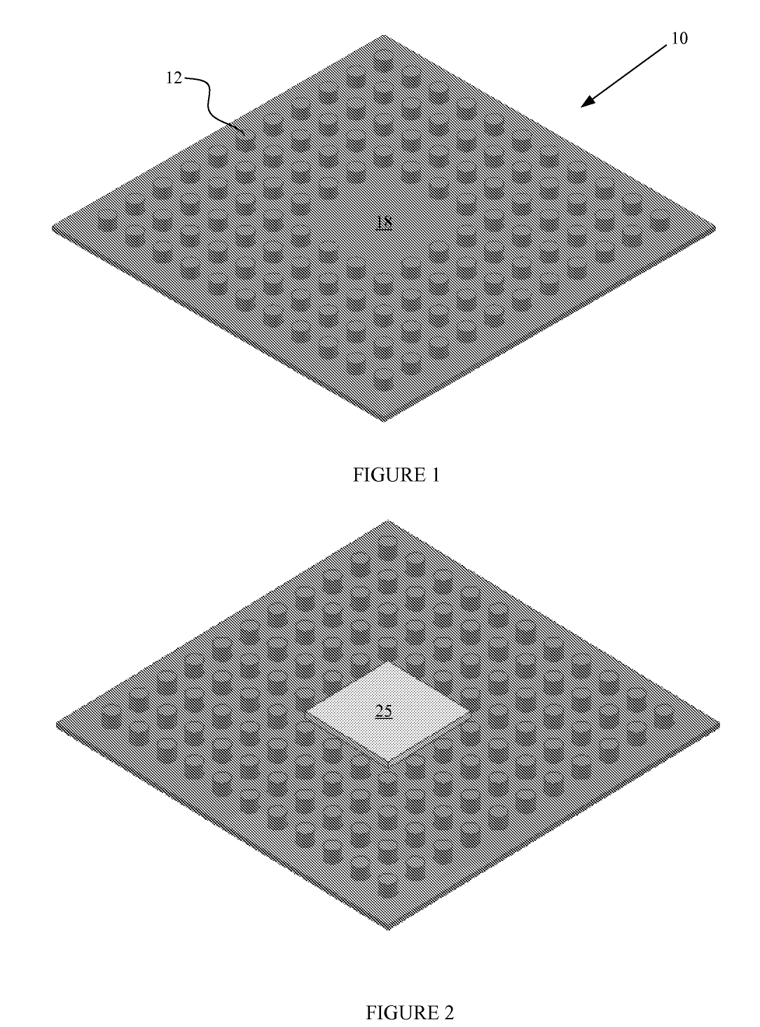

Next, as shown in FIG. 2, a first semiconductor die 25 (or die) containing an IC device is disposed on the DAP 18. The die 25 may be made of any suitable semiconductor material. Some non-limiting examples of such materials may include silicon, gallium arsenide, silicon carbide, gallium nitride, silicon and germanium, and combinations thereof.

The first die 25 can contain any number of IC devices. The IC device(s) may be any known integrated circuit (including any discrete device) in the art. Some non-limiting examples of these devices may include logic or digital IC device, linear regulators, audio power amplifiers, LDO, driver IC, diodes, and/or transistors, including zener diodes, schottky diodes, small signal diodes, bipolar junction transistors (“BJT”), metal-oxide-semiconductor field-effect transistors (“MOSFET”), insulated-gate-bipolar transistors (“IGBT”), and insulated-gate field-effect transistors (“IGFET”).

Any known flipchip process can be used to attach the first die 25 to the DAP 18. In these embodiments, the IC device(s) on the first die 25 can be provided with a bond pad as known in the art. In some embodiments, the bond pads can be provided in those areas that overlay the IC device(s). The bond pads can be formed in the desired location by any process known in the art (such as a redistribution method) and can be made of any known solderable material, including Au, Cu, Ag, Ti, Ni, Sn, W, Ni, or combinations thereof.

An array of solder bumps (or pillars) can then be provided on the bond pads. The bumps can be made of conductive material such as Ag, Sn, Pb, Cu, Sb, Au or combinations thereof. The bumps can be provided on the bond pads through any process known in the art, including electroless plating, ball drop, or printing. Then, the die 25 is flipped and placed on the interconnect structure so the bond pad (through the bumps) is attached to the desired locations of the DAP 18, as shown in FIG. 2.

In some embodiments, the DAP 18 can be altered prior to the first die 25 being attached to it. In these embodiments, a solder mask (or resist) layer could be formed on the DAP 18. Alternatively, solder-confining features like embossed or cavity-etched features could be formed on the DAP 18. The solder mask and solder-confining features can be used to aid in the attachment process because they align with the bond pads/bumps formed on the first die 25 and prevent the solder from reflowing excessively that can cause solder bridging.

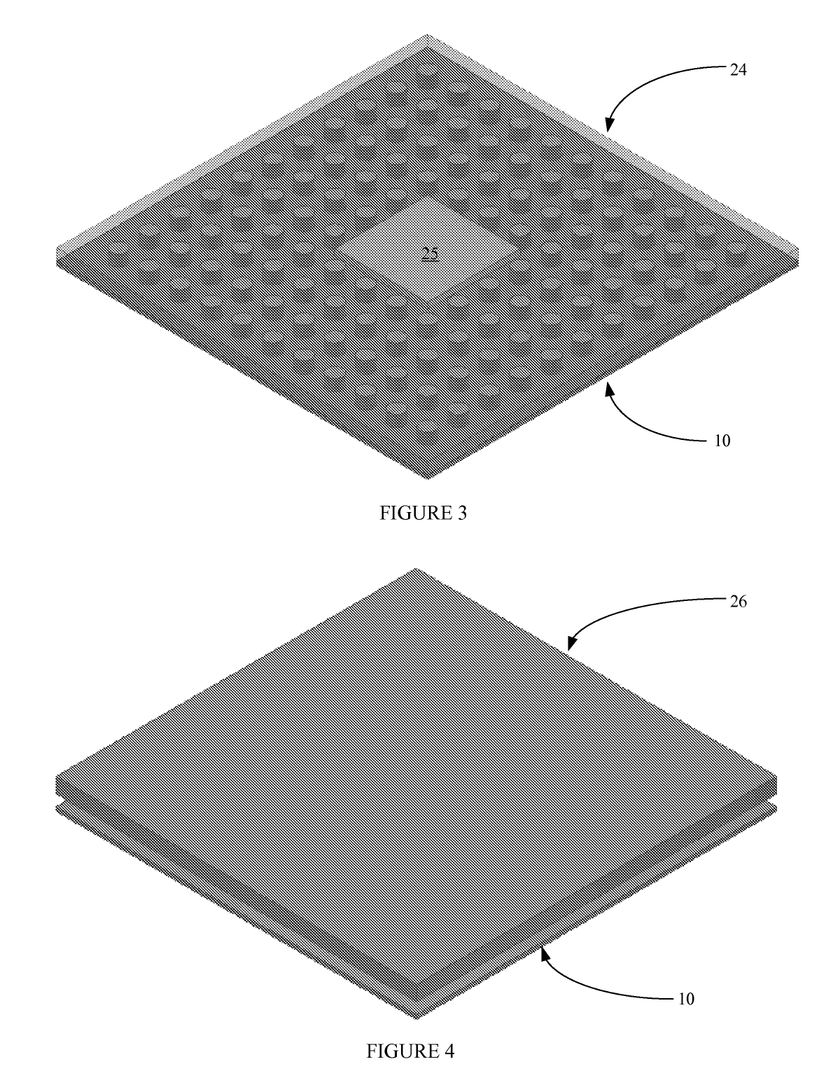

As shown in FIG. 3, a first pre-molding layer 24 can then be provided on the lead frame 10 so that the upper surface of the vias 12 are exposed. The pre-molding layer 24 can be made of any material known in the art, such as an epoxy molding compound, a thermoset resin, a thermoplastic material, or a potting material. The pre-molding layer 24 can be provided in any manner known in the art. In some embodiments, such as where the pre-molding layer is made of potting material, it is deposited on the lead frame 10 by dispensing and then planarizing by any physical action until the upper surfaces of the vias and the pads are exposed.

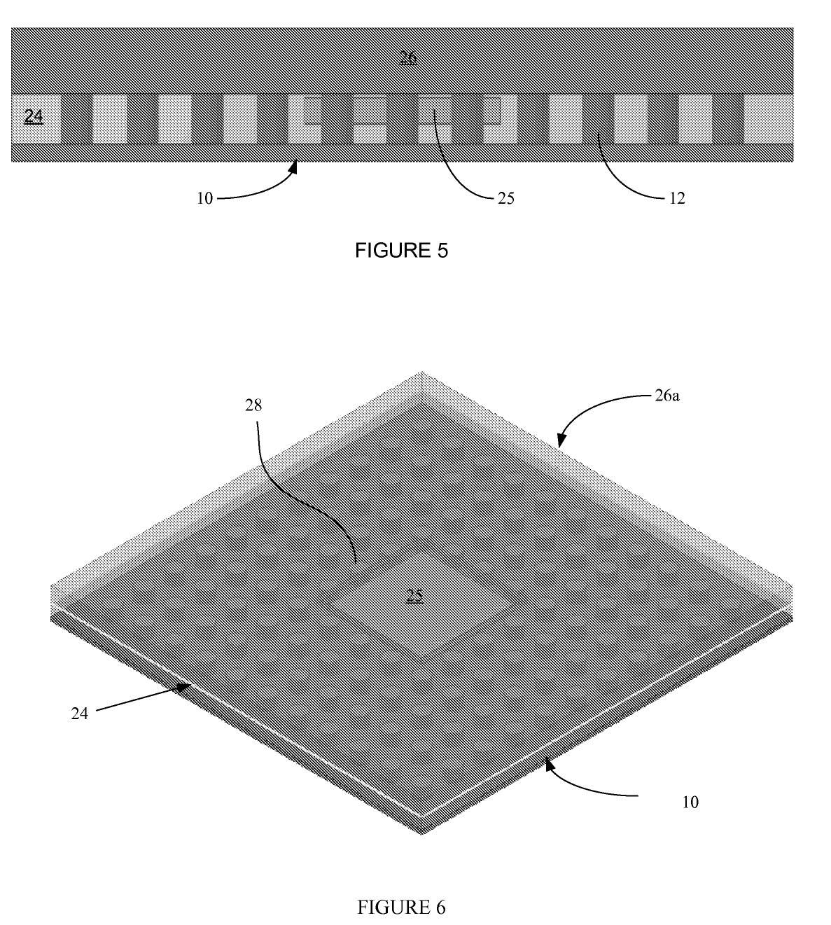

As shown in FIG. 4 (with a side view depicted in FIG. 5), a metal cladding layer 26 can then be provided on the pre-molding layer 24 and the upper surfaces of the vias. In some embodiments, the metal cladding layer 26 can comprise any piece of metal that can be configured with the desired size and then placed using any known method, such as welding or bonding, on the first pre-molding layer 24 and the upper surfaces of the vias. The metal cladding layer 26 can comprise any conductive metal or metal alloy known in the art, including Cu, Ni—Pd, Ni—Pd—Au, Fe, Ni—Pd—Au/Ag, or combinations thereof. In some embodiments, the metal cladding layer comprises Cu. The metal cladding layer 26 can have any size and thickness that will substantially match the size of the leadframe. In some embodiments, the metal cladding layer can be substantially rectangular with a thickness ranging from about 75 to about 250 μm.

In other embodiments, the structure containing the metal cladding layer depicted in FIGS. 4 and 5 can be formed using another method. In these embodiments, the metal cladding layer 26 is first provided on the vias 12 by welding or bonding. Then, the first pre-molding layer 24 is provided in the empty spaces between the lead frame 10, the vias 12, and the metal cladding layer 26 by transfer molding.

In some embodiments, a cavity can be provided between the first die 25 and the metal cladding layer. The cavity is incorporated into the semiconductor packages to make sure there exists proper clearance (and therefore insulation) between the first die 25 and the interconnect structure formed from the metal cladding layer.

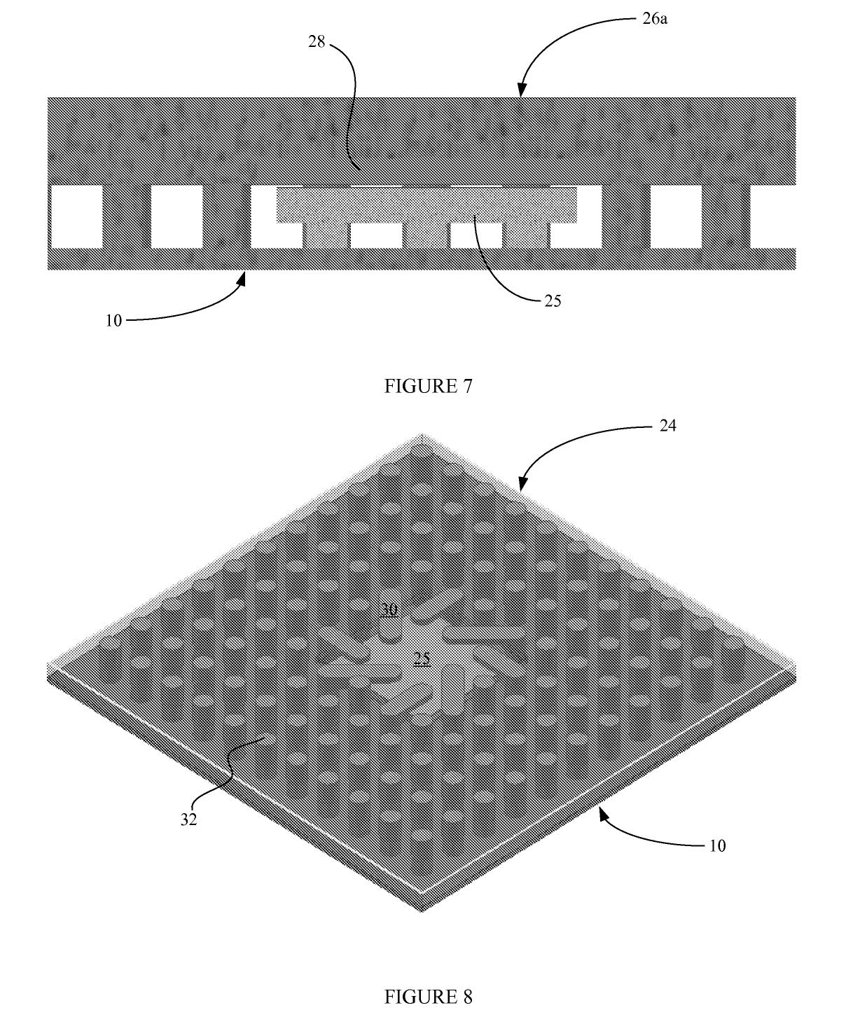

In these embodiments, the metal cladding layer 26a is made with an opening formed therein. When the metal cladding layer 26a is then attached to the vias 12, a cavity 28 is then created between the first die 25 and the metal cladding layer 26a. One example of the cavity 28 can be seen in plan view in FIG. 6 (which shows the metal cladding layer 26a as transparent) and the side view in FIG. 7 (which does not show the pre-molding layer 24 for purposes of clarity). The size of the cavity 28 is selected so that the function described above can be achieved given the size of the first die 25. In some embodiments, the cavity 28 can have a thickness ranging from about 50 μm to about 100 μm. After the cavity 28 has been formed, the remainder of the manufacturing process remains the same as those embodiments where no cavity has been formed.

Once the first pre-molding layer 24 has been formed, the metal cladding layer 26 can then be etched. The metal cladding layer 26 can be etched using any known chemical etching process, such as photomask etching. The result of the etching process includes the formation of an interconnect structure containing routing leads 30 which run from the vias 12 to the backside of the first die 25. As shown in FIG. 8, the leads 30 run towards the interior of the semiconductor package. The leads 30 can be configured or customized to substantially match the desired connection points in the second semiconductor die that will be located thereon in the completed semiconductor package. Thus, for the semiconductor package that contains a high pin integrated circuit as illustrated in the Figures, the leads 30 are configured as a combination of lines. Of course, other shapes can be used for the leads 30 including substantially rectangular, circular, or any other known geometrical shapes. The etching process will also form extensions of the vias (first via extensions 32) which will extend the height of the vias 12.

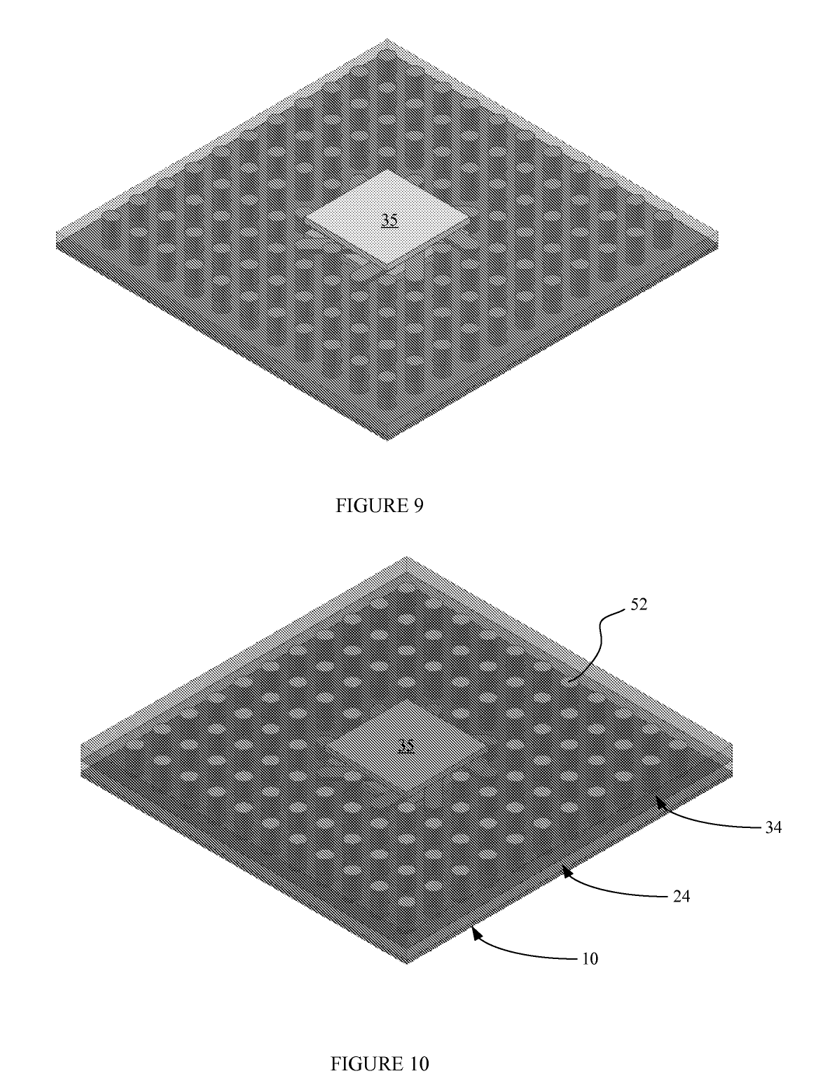

Next, as shown in FIG. 9, a second semiconductor die (or IC die) 35 is attached to the routing leads 30. The second die 35 may be made of the same or different materials than those used in the first die. The second die 35 can contain any number of IC devices that may be the same or different than the device(s) used in the first die 25.

The second semiconductor die 35 can be attached to the routing leads 30 using any known flipchip process. Accordingly, similar to the first semiconductor die, bond pads are formed on the desired locations of the IC die(s) and bumps are applied to the bonds pads. The die 35 is then flipped and attached so that the bond pads are attached to the desired locations of the routing leads 30 through the bumps.

As shown in FIG. 10, a second pre-molding layer 34 can then be provided so that the upper surface extensions 32 of the vias are exposed. The second pre-molding layer 34 can be made of the same or different than the material used for the first pre-molding layer 24. The second pre-molding layer 34 can be provided in any manner known in the art, including the process used to make the first pre-molding layer 24.

A second metal cladding layer can then be provided on the second pre-molding layer 34 and the upper surfaces via extensions 32. The second metal cladding layer can be made of the same or different than the material used for the first metal cladding layer 26. The second metal cladding layer can be provided in any manner known in the art, including the process used to make the first metal cladding layer 26. The second metal cladding layer can optionally contain a cavity similar to the cavity 28 in the first metal cladding layer. In some embodiments, similar to those described above, the second metal cladding layer can be disposed on the via extensions 32 before the second pre-molded layer 34 is formed.

The second metal cladding layer can then be etched. The second metal cladding layer 36 can be etched using any known chemical etching process, including one that is the same or different than the etching process for the first metal cladding layer 26. The result of the etching process includes the formation of a second interconnect structure containing routing leads 50 which run from the vias extensions 32 to the backside of the second die 35. As shown in FIG. 11, the leads 50 run towards the interior of the semiconductor package. The leads 50 can be configured or customized to substantially match the desired connection points in the third semiconductor die that will be located thereon in the completed semiconductor package. Thus, the leads 50 can be configured as a combination of lines as depicted in FIG. 11. Of course, other shapes can be used for the leads 50 including substantially rectangular, circular, or any other known geometrical shapes. The etching process will also form second extensions of the vias (second via extensions 52) which will extend the height of the vias.

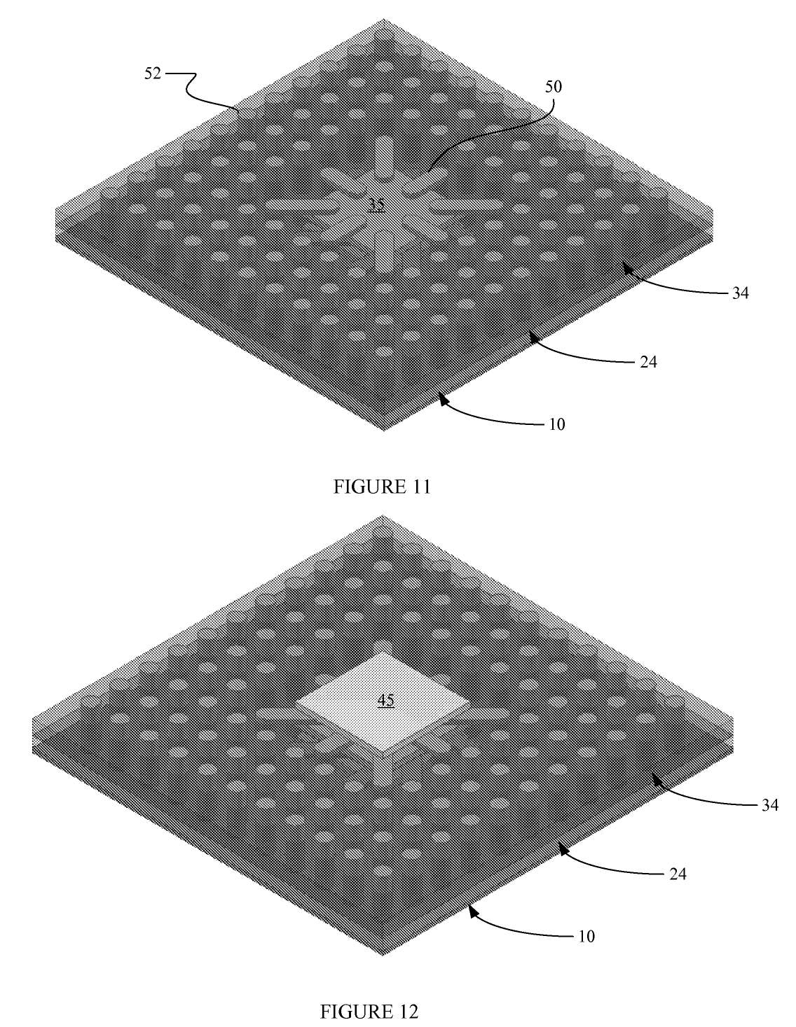

Next, as shown in FIG. 12, a third semiconductor die (or IC die) 45 is attached to the routing leads 50. The third die 45 may be made of the same or different materials than those used in the first die. The third die 45 can contain any number of IC devices that may be the same or different than the device(s) used in the first die 25.

The third semiconductor die 45 can be attached to the routing leads 50 using any known flipchip process. Accordingly, similar to the first semiconductor die, bond pads are formed on the desired locations of the IC die(s) and bumps are applied to the bonds pads. The third die 45 is then flipped and attached so that the bond pads are attached to the desired locations of the routing leads 50 through the bumps.

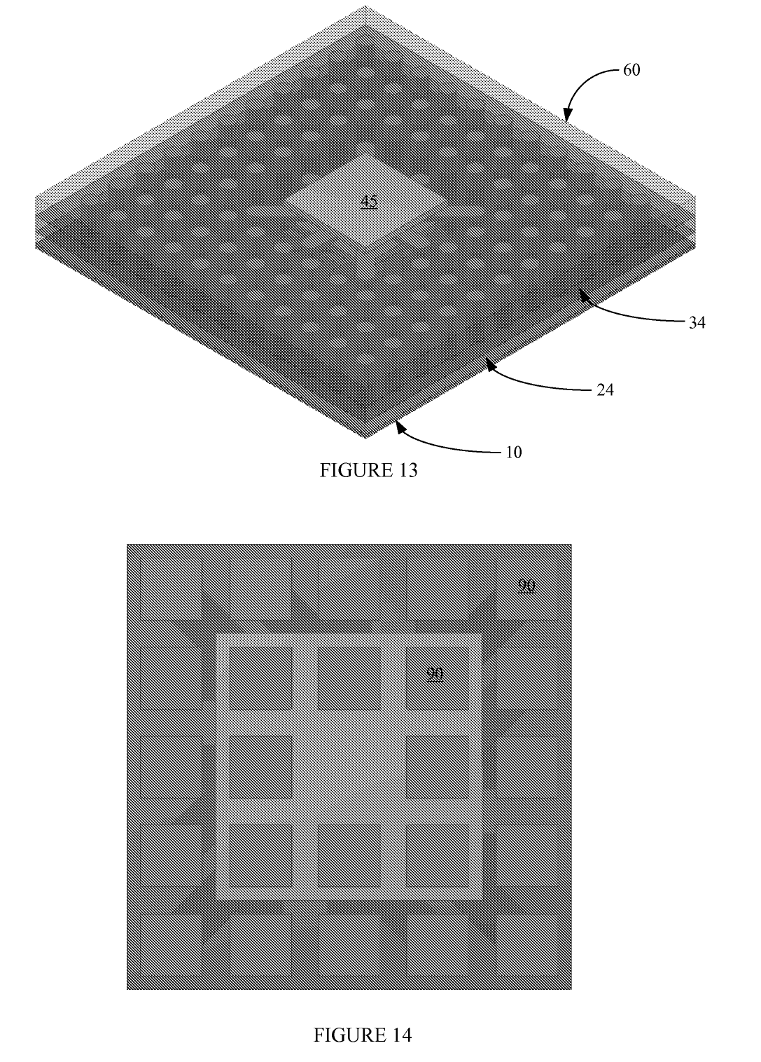

An encapsulation process is then performed on the resulting structure. The encapsulation process uses any molding material known in the art. In some embodiments, the molding material can comprise an epoxy molding compound, a thermoset resin, a thermoplastic material, or potting material. In other embodiments, the molding material comprises an epoxy molding compound. In FIG. 13, the molding material 60 is shown in phantom to better illustrate the internal components of semiconductor package. The molding material 60 does not encapsulate the components already encapsulated by the first pre-molding layer 24 or the second pre-molding layer 34. The molding material 60, however, can cooperate with both of these pre-molding layers to encapsulate the desired components of the semiconductor package except for the land pad array.

The leadframe 10 is then etched to form the array of land pads 90 (or lands). The etching results in the formation of lands having an array that is configured for the external electronic device to which the semiconductor package will be attached (such as a printed circuit board). The land pads (or lands) can have any configuration known in the art consistent with their operation as terminals for the semiconductor package. Thus, in the illustrated embodiments, the lands are given a substantially rectangular configuration with a size ranging from about 0.30 mm² to about 0.50 mm². In other embodiments, though, the lands can have a round or other geometrical shape.

Any etching process known in the art can be used to form the land pad array, including photomask etching and mechanical mask etching. One example of one land pad array is depicted in FIG. 14 which shows a bottom view of the semiconductor package. In some embodiments, the configuration of the land pads is the combination of the vias and their extensions. The land pad array can be routed and customized for a wide variety of configurations. This allows the semiconductor package to be configured with many different sizes and shapes that can accommodate different sizes of dies and different IC devices contained in the dies.

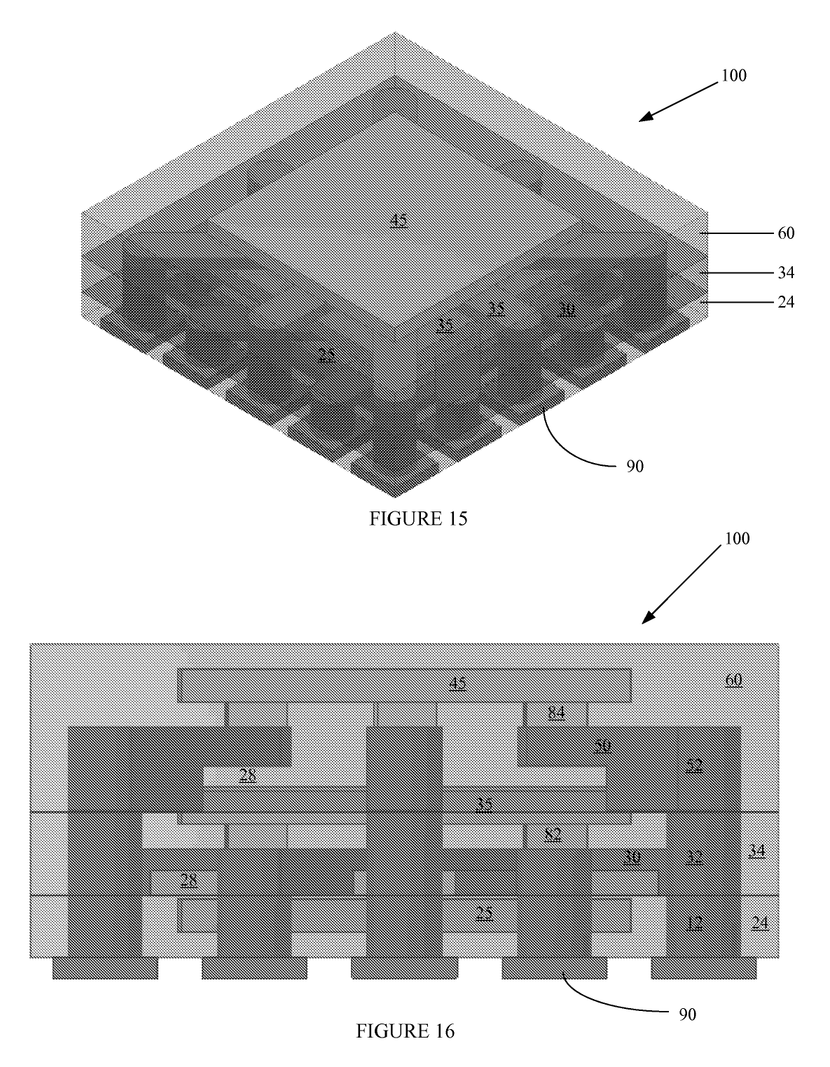

The resulting structure can be singulated into individual semiconductor packages 100. The singulation can be carried out using any process known in the art, including a saw singulation process. The semiconductor package 100, as shown in FIG. 15, can then be marked, taped, and reeled using any process known in the art.

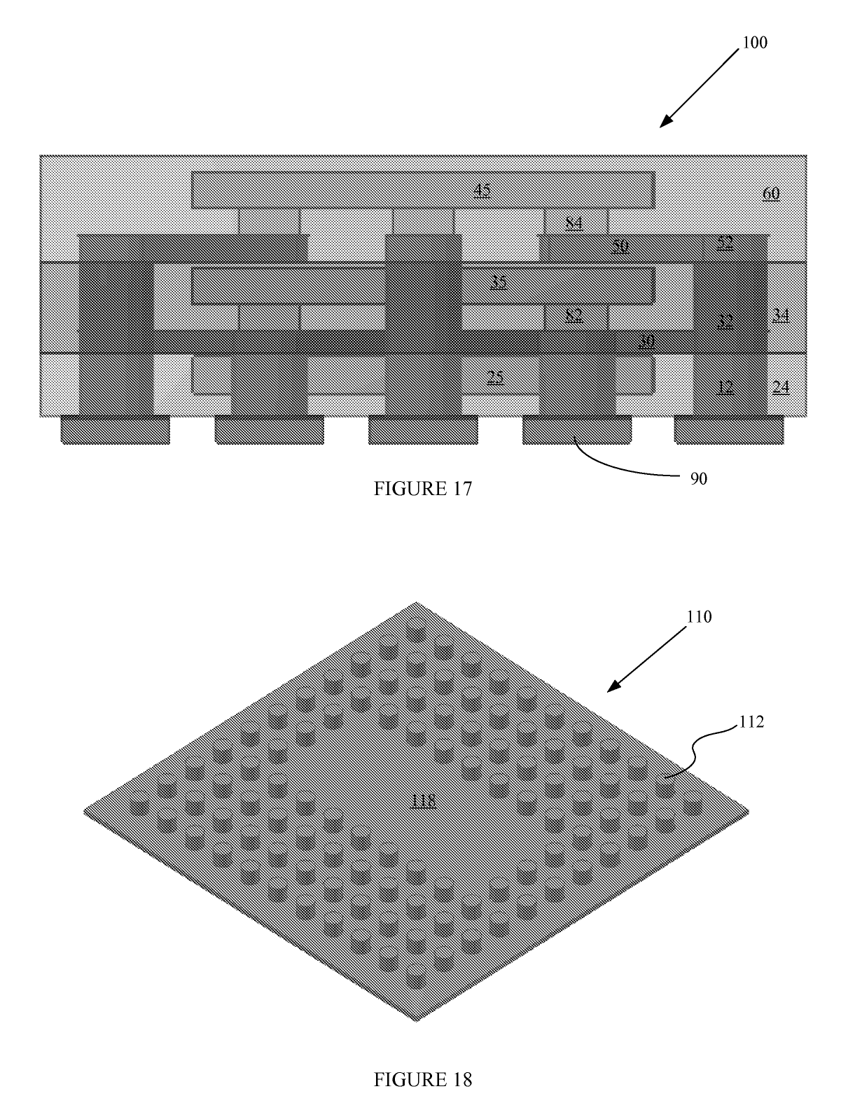

The completed semiconductor package 100 is shown in the side views depicted in FIGS. 16 and 17. FIG. 16 illustrates the embodiments where the semiconductor package contains a cavity 28 while FIG. 17 illustrates the embodiments where the semiconductor package does not contain a cavity. The package 100 contains the first pre-molding layer 24, second pre-molding layer 34, and the molding material 60 that together encapsulate the package 100. The lands 90 remain exposed and are configured in a stand-off position so that they can be attached to the PCB. The lands operate to connect the first die 25 to the PCB. The routing leads 30 serve to connect the second die 35(containing bond pads 82) to the PCB, and the routing leads 50 operate to route the electrical signals from the IC device in the third die 45 (containing bond pads 84) to the PCB.

Other embodiments of the semiconductor packages and methods for making such packages are shown in FIGS. 18-26. In these embodiments, the methods used to form the semiconductor packages can be substantially similar to those described for FIG. 1-17 and therefore will not be repeated.

The methods for making the semiconductor packages begin by providing a leadframe 110 which is substantially similar to leadframe 10. The leadframe 110 is configured to contain a die attach pad 118 bigger than DAP 18. This allows the leadframe 110 to have multiples dies placed on its surface. In the embodiments depicted in FIG. 18, the leadframe 110 can have a DAP 118 that is configured to support two semiconductor dies. The number of dies supported by DAP 118 will be limited by the system electrical design and target package size.

Next, vias 112 can be provided on the upper surface of the lead frame 110 if the leadframe is not made with vias 112 already present. The vias 112 can be substantially similar to vias 12, with the exception of the number and layout of the vias 112.

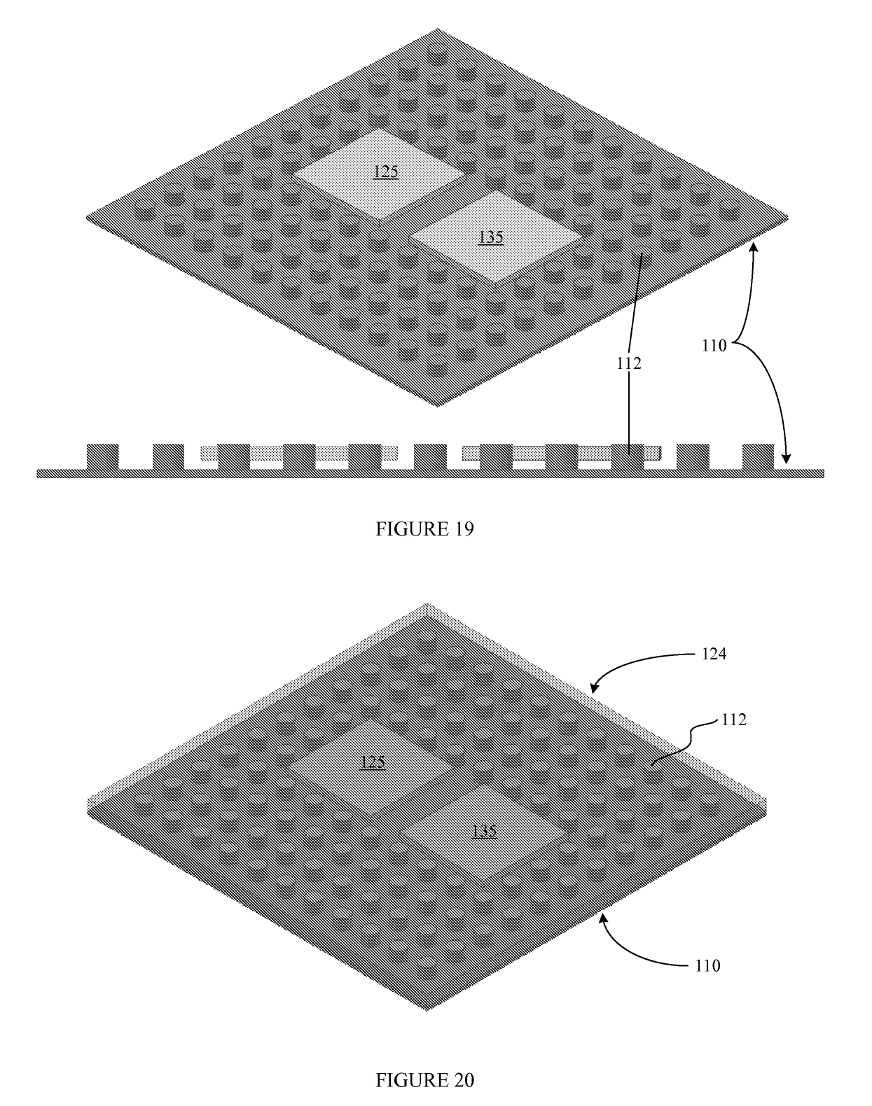

Next, as shown in FIG. 19, a first semiconductor die 125 (or first die) and a second semiconductor die 135 are disposed on the DAP 118. The first and second semiconductor dies 125 and 135 may be of a substantially similar material as first die 25 and second die 35. The first die 125 and second die 135 can also contain any number of IC devices, which can be the same or different than the dies 25 and 35. Any known flipchip process can be used to attach the first die 125 and the second die 135 to the DAP 118. In some embodiments, the DAP 118 can be altered (like DAP 18) prior to the first die 125 and second die 135 being attached to it.

As shown in FIG. 20, a first pre-molding layer 124 can then be provided on the lead frame 110 so that the upper surface of the vias 112 are exposed. The pre-molding layer 124 can be made of any material known in the art and can be provided in any manner known in the art, including those described herein. A metal cladding layer (similar to the metal cladding layer 26) can then be provided on the pre-molding layer 124. In other embodiments, the metal cladding layer can be provided on the vias 112 and then the pre-molding layer 124 formed using the methods described herein. And in some embodiments, a cavity can be provided between the first die 125 (and/or the second die 135) and the metal cladding layer using methods similar to those described for cavity 28.

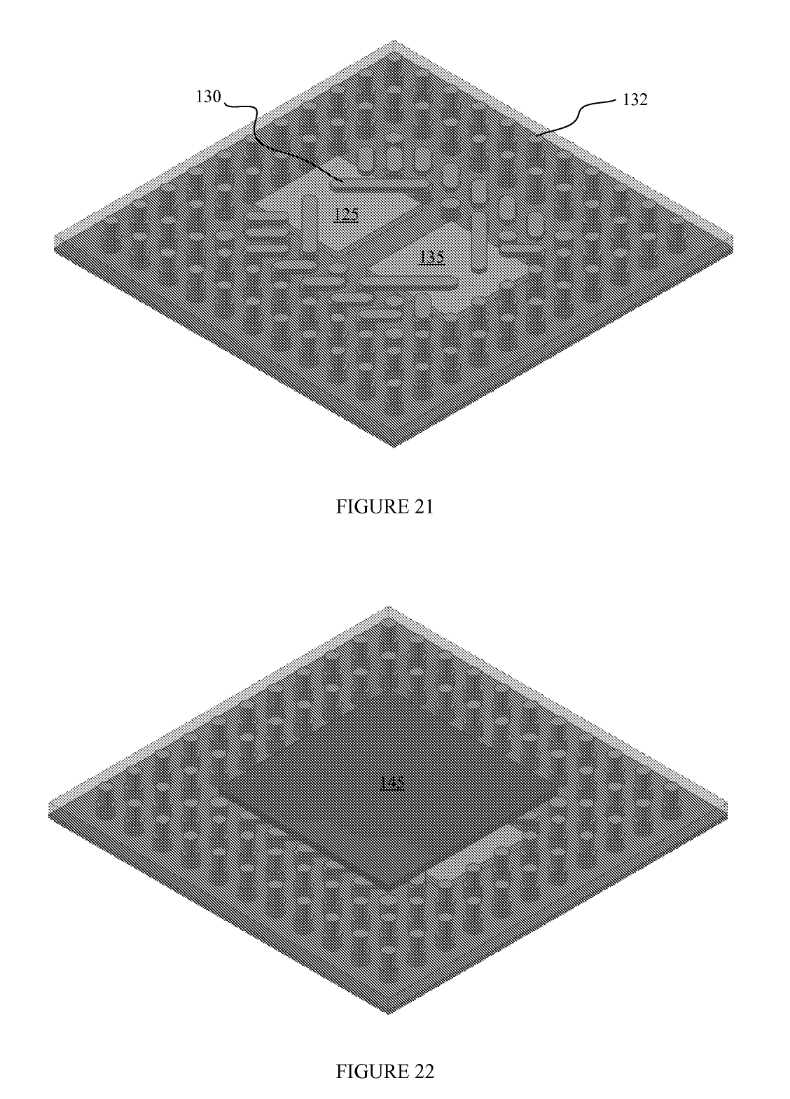

The metal cladding layer can then be etched to form an interconnect structure containing routing leads 130 which run from the vias 112 to the backside of the first die 125 and/or the second die 135. As shown in FIG. 21, the leads 130 run towards the interior of the semiconductor package. The leads 130 can be configured similar or customized to substantially match the desired connection points in the third semiconductor die that will be located thereon in the completed semiconductor package. Thus, for the semiconductor package that contains a high pin integrated circuit as illustrated in the Figures, the leads 130 are configured as a combination of lines. The etching process will also form extensions of the vias (via extensions 132) which will extend the height of the vias 112.

Next, as shown in FIG. 22, a third semiconductor die 145 is attached to the routing leads 130. The third die 145 may be made of the same or different materials than those used in the first die 125 and/or second die 135. The third die 145 can contain any number of IC devices that may be the same or different than the device(s) used in the first die 125 and/or second die 135. The third semiconductor die 145 can be attached to the routing leads 130 using any known flipchip process, including those described herein.

Depending on the system electrical design and target package size, more than a single die can be incorporated on the routing leads 130. As well, depending on the system electrical design and target package size, additional routing leads could be formed over the third die and an additional die could be provided over these additional routing leads.

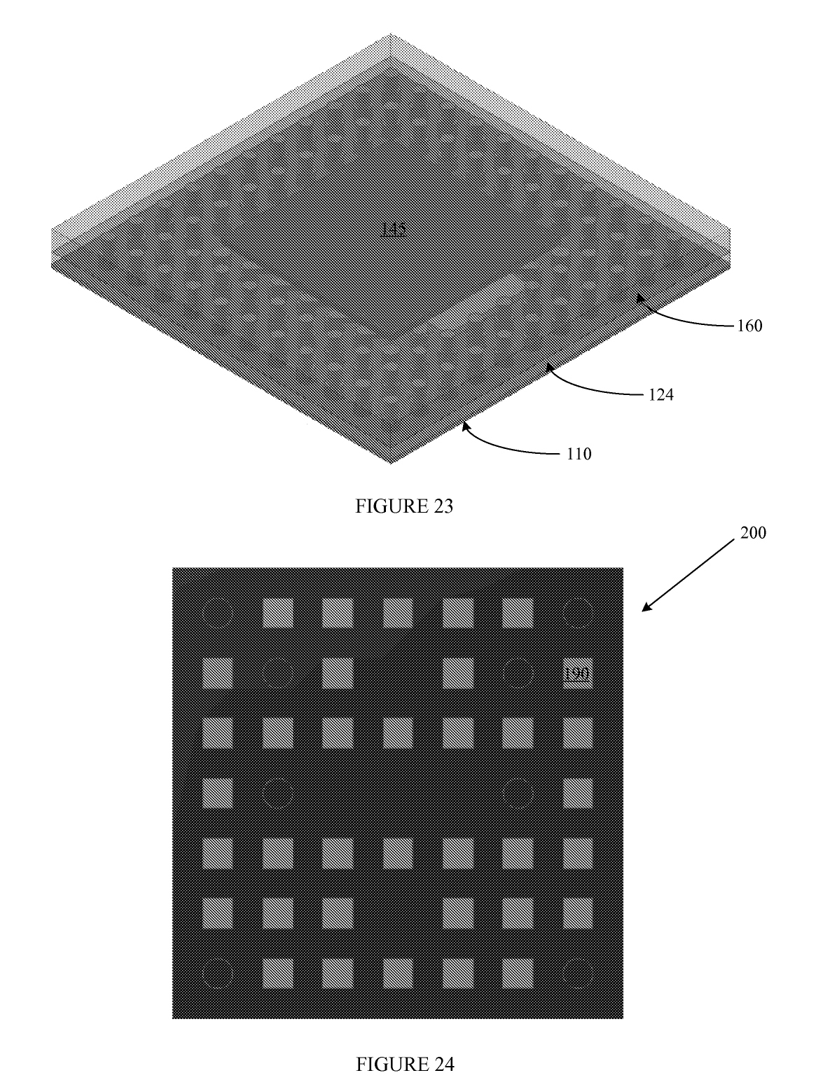

An encapsulation process is then performed on the resulting structure. The encapsulation process uses any molding material known in the art, including those described herein. In FIG. 23, the molding material 160 is shown in phantom to better illustrate the internal components of semiconductor package. The molding material 160 does not encapsulate the components already encapsulated by the first pre-molding layer 124. The molding material 160, however, can cooperate with this pre-molding layer to encapsulate the desired components of the semiconductor package except for the land pad array.

The leadframe 110 is then etched to form the array of land pads 190 (or lands) that is configured for the external electronic device to which the semiconductor package will be attached (i.e., PCB). Any etching process known in the art can be used to form the land pad array, including those used to form land pads 90. The land pads (or lands) 190 can have any configuration known in the art consistent with their operation as terminals for the semiconductor package, including those described herein. One example of one land pad array is depicted in FIG. 24 which shows a bottom view of the semiconductor package 200. The land pad array can be routed and customized for a wide variety of configurations. This allows the semiconductor package to be configured with many different sizes and shapes that can accommodate different sizes of dies and different IC devices contained in the dies.

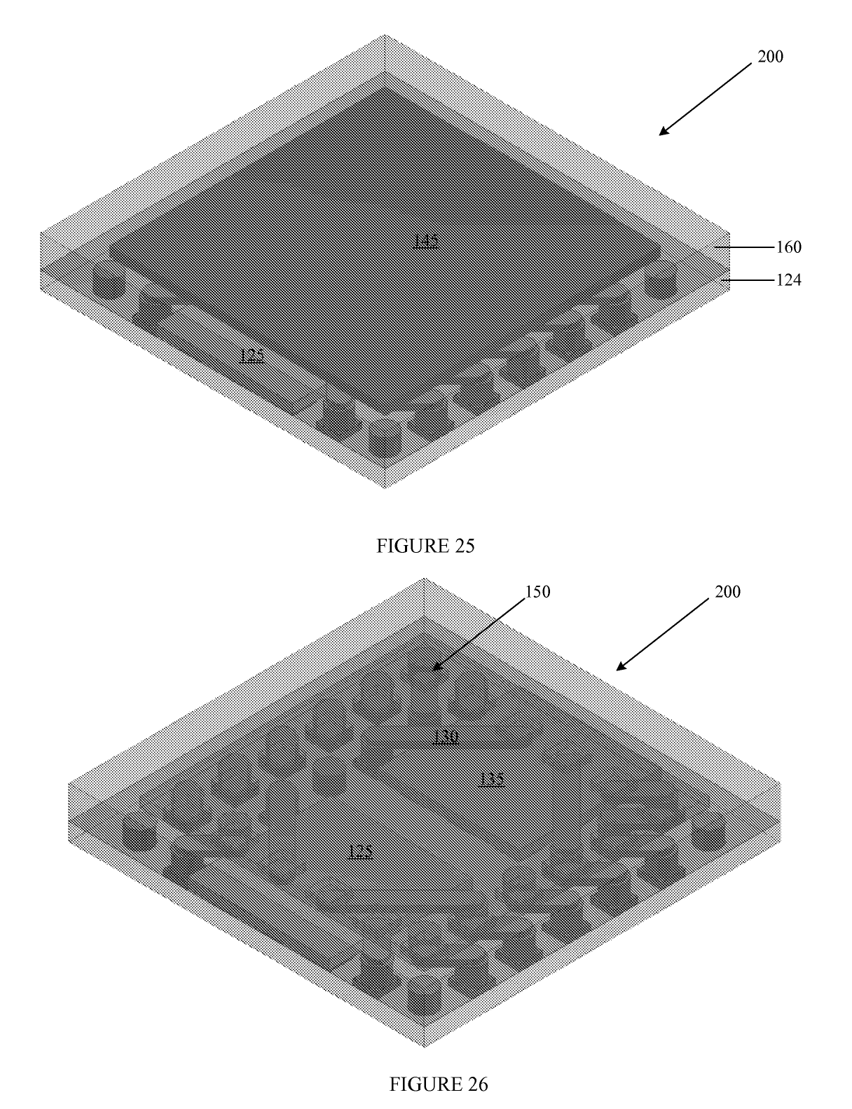

The resulting structure can be singulated into individual semiconductor packages 200. The singulation can be carried out using any process known in the art, including a saw singulation process. The semiconductor package 200, as shown in FIG. 25, can then be marked, taped, and reeled using any process known in the art.

The completed semiconductor package 200 is shown in FIGS. 25 and 26 (with FIG. 26 showing a transparent third die 145 so the underlying components can be seen). FIGS. 25 and FIG. 26 illustrate a semiconductor package 200 that contains both the pre-molding layer 124 and the molding material 160 that together encapsulate the package 200. The lands 190 remain exposed and are configured in a stand-off position so that they can be attached to the PCB. The lands operate to connect the first die 125 and the second die 135 to the PCB. The routing leads 130 serve to connect the third die 145 to the PCB using bond pads 150.

The semiconductor packages described herein have several features. These packages contain multiple semiconductor dies that can be manufactured more efficiently that eliminates multiple singulation process when using stackable micro-leadframe packages (MLP) because the chips are stacked completely prior to any singulation. The packages are also relatively thin with a thickness ranging from about 0.50 mm to about 1 mm while also have the capability of a full land pad array. The metal layering provided by the leadframe and metal cladding layers provide a high degree of routing flexibility and provide an optimal bonding layout. The packages have a higher input/output (I/O) capability with a smaller package footprint when compared to conventional semiconductor packages.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor package, comprising:
a land pad array comprising a middle portion and an outer portion;
a first die containing an integrated circuit device resting on the middle portion of the land pad array;
a second die containing an integrated circuit device disposed over the first die and resting on first routing leads that are connected to part of the outer portion of the land pad array;
a third die containing an integrated circuit device disposed on the backside of the second die and resting on second routing leads that are connected to part of the outer portion of the land pad array; and
a molding material.

2. The semiconductor package of claim 1, wherein the land pad array is formed by etching and can be used for different package sizes.

3. The semiconductor package of claim 1, wherein the lands of the land pad array are not physically connected to each other.

4. The semiconductor package of claim 1, wherein the molding material comprises a first portion partially encapsulating the land pad array and the first die, a second portion encapsulating the first routing leads and the second die, and a third portion encapsulating the second routing leads and the third die.

5. The semiconductor package of claim 4, wherein the first portion, the second portion, and third portion of the molding material are formed separately.

6. The semiconductor package of claim 1, wherein the first routing leads are formed by etching a first metal cladding layer.

7. The semiconductor package of claim 6, wherein the second routing leads are formed by etching a second metal cladding layer.

8. A semiconductor package, comprising:
a land pad array comprising a middle portion and an outer portion;
a first die containing an integrated circuit device resting on part of the middle portion of the land pad array;
a second die containing an integrated circuit device resting on the part of the middle portion of the land pad array;
a third die disposed over the first and second dies and resting on routing leads that are connected to the outer portion of the land pad array; and
a molding material.

9. The semiconductor package of claim 8, wherein the lands of the land pad array are not physically connected to each other.

10. The semiconductor package of claim 8, wherein the molding material comprises a first portion partially encapsulating the land pad array, the first die, and the second die and a second portion encapsulating the routing leads and the third die.

11. The semiconductor package of claim 10, wherein the first portion of the molding material and the second portion of the molding material are formed separately.

12. The semiconductor package of claim 8, wherein the routing leads are formed by etching a metal cladding layer.

13. An electronic device containing a semiconductor package, the package comprising:
a land pad array comprising a middle portion and an outer portion;
a first die containing an integrated circuit device resting on the middle portion of the land pad array;
a second die containing an integrated circuit device disposed over the first die and resting on first routing leads that are connected to part of the outer portion of the land pad array;
a third die containing an integrated circuit device disposed on the backside of the second die and resting on second routing leads that are connected to part of the outer portion of the land pad array; and
a molding material.

14. An electronic device containing a semiconductor package, the package comprising:
a land pad array comprising a middle portion and an outer portion;
a first die containing an integrated circuit device resting on part of the middle portion of the land pad array;
a second die containing an integrated circuit device resting on the part of the middle portion of the land pad array;
a third die disposed over the first and second dies and resting on routing leads that are connected to the outer portion of the land pad array; and
a molding material.

15. A method for making semiconductor package, comprising:
providing a lead frame containing an array of vias;
attaching a first die containing an integrated circuit device to a die attach pad of the leadframe;
providing a first molding material around the array of vias and the first die so that the upper surfaces of the vias are exposed;
providing first routing leads from the vias to the backside of the first die;
attaching a second die containing an integrated circuit device to the first routing leads;
providing a second molding material around the first via extensions and the second die so that the upper surfaces of the via extensions are exposed;
providing second routing leads from the vias to the backside of the second die;
attaching a third die containing an integrated circuit device to the second routing leads;
providing a third molding material to encapsulate the second routing leads and third die; and
etching the lead frame to form a land pad array.

16. The method of claim 15, wherein the land pads of the land pad array are not physically connected to each other.

17. The method of claim 15, including forming the first routing leads by attaching a metal cladding layer to the upper surfaces of the vias and then etching the metal cladding layer.

18. The method of claim 17, wherein the process of providing the first routing leads also provides an extension to the vias.

19. The method of claim 18, including forming the second routing leads by attaching a metal cladding layer to the upper surfaces of the via extensions and then etching the metal cladding layer.

20. The method of claim 17, wherein the process of providing the second routing leads also provides a second extension to the vias.

21. A method for making semiconductor package, comprising:
providing a lead frame with an array of vias and a die attach pad;
attaching a first die containing an integrated circuit device to the die attach pad;
attaching a second die containing an integrated circuit device to the die attach pad;
providing a first molding material around the array of vias, the first die, and the second fie so that the upper surfaces of the vias are exposed;
providing routing leads from the vias to the backside of the first die and the second die;
attaching a third die containing an integrated circuit device to the routing leads;
providing a second molding material around the second routing leads and third die; and
etching the lead frame to form a land pad array.

22. The method of claim 21, wherein the land pads of the land pad array are not physically connected to each other.

23. The method of claim 21, including forming the routing leads by attaching a metal cladding layer to the upper surfaces of the vias and then etching the metal cladding layer.

24. The method of claim 23, wherein the process of providing the routing leads also provides an extension to the vias.

25. The method of claim 21, wherein the first and second molding material encapsulate the package except for the land pad array.
